(19) United States
(12) Patent Application Publication
(10) Pub. No.: US 2024/0094314 A1
(43) Pub. Date: Mar. 21, 2024

(54) MULTIPLE COBALT IRON BORON LAYERS IN A FREE LAYER OF A MAGNETORESISTIVE SENSING ELEMENT

(71) Applicant: Infineon Technologies AG, Neubiberg (DE)

(72) Inventors: Bernhard ENDRES, Nabburg (DE); Klemens PRUEGL, Regensburg (DE); Juergen ZIMMER, Neubiberg (DE); Michael KIRSCH, Regensburg (DE); Milan AGRAWAL, Muenchen (DE)

(21) Appl. No.: 17/932,508

(22) Filed: Sep. 15, 2022

(51) Int. Cl. G01R 33/09

(52) U.S. Cl. CPC G01R 33/098

(57) ABSTRACT

A tunnel magnetoresistive (TMR) sensing element may include a free layer. The free layer of the TMR sensing element may include a first cobalt iron boron (CoFeB) layer, an interlayer over the first CoFeB layer, a second CoFeB layer over the interlayer, and a nickel iron (NiFe) layer over the second CoFeB layer.

### BACKGROUND

A magnetic tunnel junction (MTJ) includes two ferromagnetic layers that are separated by a comparatively thin insulator layer, referred to as a tunnel barrier. The tunnel barrier layer is sufficiently thin to permit electrons to tunnel from one ferromagnetic layer to the other ferromagnetic layer when a bias voltage is applied between a pair of contact electrodes. In an MTJ, a tunneling current depends on the relative orientation of magnetizations of the two ferromagnetic layers, which can be changed by an applied magnetic field. This phenomenon is referred to as the tunneling magnetoresistance (TMR) effect. A sensing element including an MTJ (referred to as a TMR sensing element) may therefore enable a strength of an applied magnetic field to be measured.

### SUMMARY

In some implementations, a tunnel magnetoresistive (TMR) sensing element includes a free layer including: a first cobalt iron boron (CoFeB) layer; an interlayer over the first CoFeB layer; a second CoFeB layer over the interlayer; and a nickel iron (NiFe) layer over the second CoFeB layer.

In some implementations, a sensor includes a magnetoresistive (MR) sensing element including: a seed layer; a reference layer over the seed layer; a tunnel barrier layer over the reference layer; a free layer over the tunnel barrier layer, wherein the free layer includes: a first CoFeB layer, a second CoFeB layer, and an interlayer between the first CoFeB layer and the second CoFeB layer, and a NiFe layer over the second CoFeB layer; and a cap layer on the free layer.

In some implementations, a method includes forming a first CoFeB layer on a tunnel barrier layer; forming an interlayer on or over the first CoFeB layer; forming a second CoFeB layer on or over the interlayer; and forming a NiFe layer on or over the second CoFeB layer.

### BRIEF DESCRIPTION OF THE DRAWINGS

FIG. 1 is a diagram illustrating an example of a conventional tunnel magnetoresistive (TMR) sensing element.

FIGS. 2A and 2B are diagrams illustrating example implementations of a TMR sensing element that has a free layer including a first cobalt iron boron (CoFeB) layer and a second CoFeB.

FIG. 3 is a diagram illustrating examples of TMR effect increases provided by the TMR sensing element including the first CoFeB layer and the second CoFeB.

FIG. 4 is a flowchart of an example process associated with fabricating the TMR sensing element including the first CoFeB layer and the second CoFeB.

### DETAILED DESCRIPTION

The following detailed description of example implementations refers to the accompanying drawings. The same reference numbers in different drawings may identify the same or similar elements.

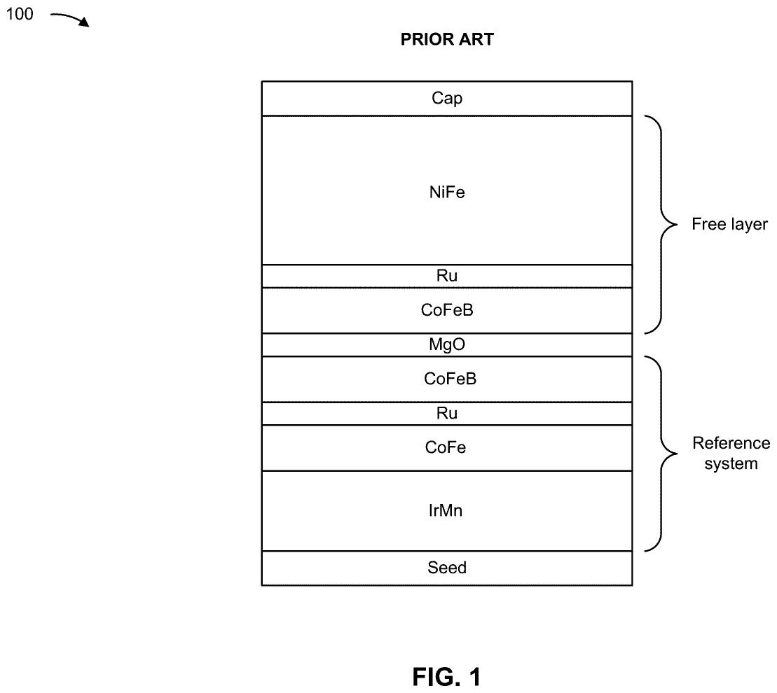

FIG. 1 is a diagram illustrating an example of a conventional tunnel magnetoresistive (TMR) sensing element 100. As shown in FIG. 1, the conventional TMR sensing element 100 includes a seed layer, a reference system, a magnesium oxide (MgO) tunnel barrier layer, a free layer, and a cap layer.

As shown in FIG. 1, the free layer in the conventional TMR sensing element 100 may include a nickel iron (NiFe) free layer to improve alignment of the free layer with an external magnetic field applied at the TMR and, in turn, reduce an angle error of the TMR sensing element (e.g., as compared to using cobalt iron (CoFe) rather than NiFe). As further shown in FIG. 1, the free layer of the conventional TMR sensing element 100 also includes a cobalt iron boron (CoFeB) free layer to increase the TMR effect at the MgO tunnel barrier layer. However, NiFe has a face centered cubic (FCC) crystal structure, which tends to decrease the TMR effect at the MgO tunnel barrier layer. Further, CoFeB is a magnetostrictive material, which can lead to increased angle error as sensed by the TMR sensing element. As a result, performance of the conventional TMR sensing element 100 may be degraded.

Some implementations described herein provide an improved TMR sensing element having a free layer that includes multiple CoFeB layers. For example, a TMR sensing element may in some implementations have a free layer that includes a first CoFeB layer, an interlayer (e.g., a tantalum (Ta) interlayer) over the first CoFeB layer, a second CoFeB layer over the interlayer, and a NiFe layer over the second CoFeB layer. In some implementations, the inclusion of the second CoFeB layer in the free layer increases the TMR effect at an MgO tunnel barrier layer of the TMR sensing element, while also reducing magnetostriction of the TMR sensing element (e.g., as compared to the conventional TMR sensing element 100 described above). Additional details are provided below.

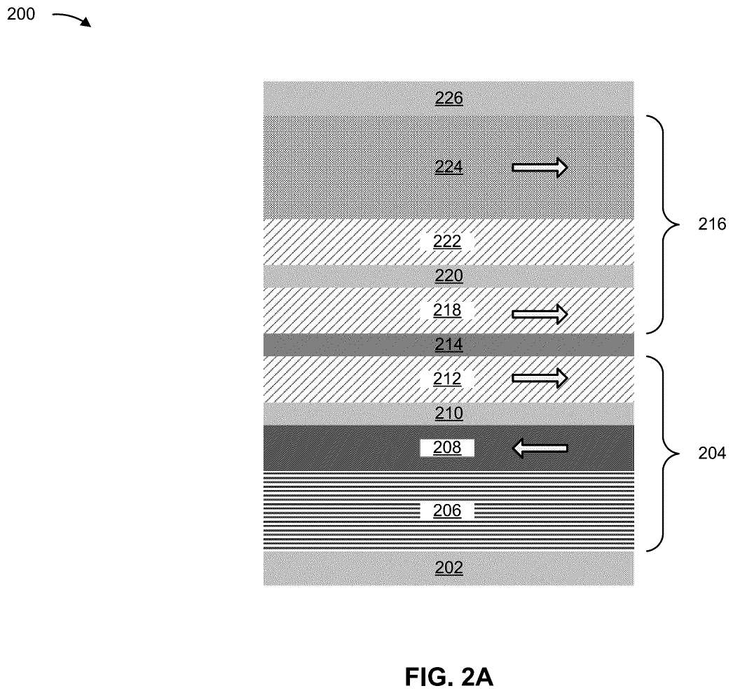

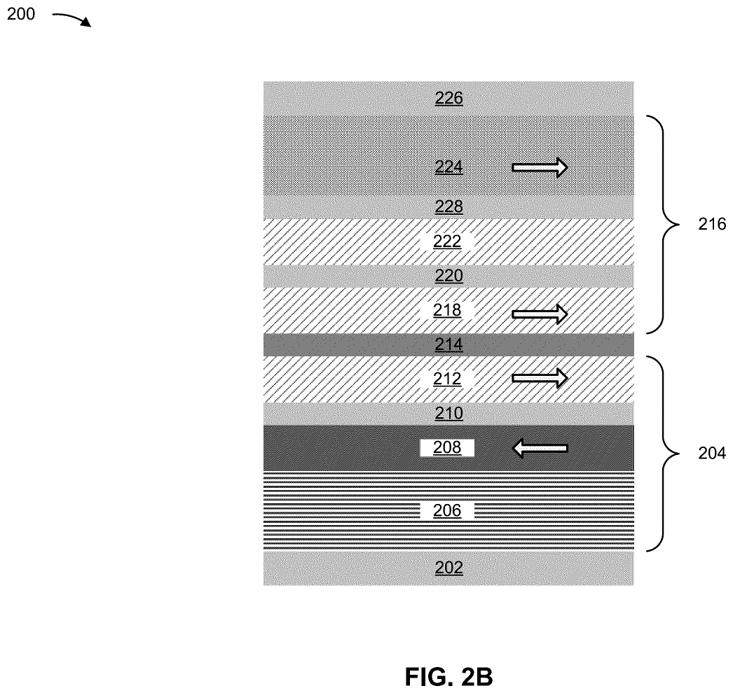

FIGS. 2A and 2B are diagrams illustrating example implementations of a TMR sensing element 200 that has a free layer including a first CoFeB layer and a second CoFeB layer. As shown in FIG. 2A, the TMR sensing element 200 may in some implementations include a seed layer 202, a reference system 204, a tunnel barrier layer 214, a free layer 216, and a cap layer 226. As shown, the reference system 204 may include an antiferromagnetic layer 206, a pinned layer 208, an interlayer 210, and a reference layer 212. As further shown, the free layer 216 may include a first CoFeB layer 218, an interlayer 220, a second CoFeB layer 222, and a NiFe layer 224.

The seed layer 202 is a layer on which other layers of the TMR sensing element 200 may be formed. In some implementations, the seed layer 202 provides electrical contact with a bottom electrode (not shown) of the TMR sensing element 200. The seed layer 202 may comprise, for example, copper (Cu), Ta, or ruthenium (Ru). In some implementations, the seed layer 202 may have a thickness in a range from approximately 15 nanometers (nm) to approximately 50 nm.

The reference system 204 is a structure designed to have a fixed direction of magnetization. As shown, the reference system 204 may be a multilayer structure that includes the antiferromagnetic layer 206, the pinned layer 208, the interlayer 210, and the reference layer 212. The antiferromagnetic layer 206 may be, for example, an iridium manganese (IrMn) layer or a platinum manganese (PtMn) layer having a thickness in a range from approximately 5 nm to approximately 30 nm. The pinned layer 208 may be, for example, a CoFe layer having a thickness in a range from approximately 1 nm to approximately 4 nm. The interlayer 210 may be, for example, a Ru layer having a thickness in a range from approximately 0.7 nm to approximately 0.8 nm. The reference layer 212 may be, for example, a CoFeB layer having a thickness in a range from approximately 1 nm to approximately 3 nm. A magnetic moment orientation of the pinned layer 208 is constrained by an effective surface magnetic field, known as an exchange bias field, which arises from the interface with the antiferromagnetic layer 206. To increase stability of the reference system 204, the pinned layer 208 is antiferromagnetically coupled to the reference layer 212 via the interlayer 210, as indicated in FIG. 2A.

The tunnel barrier layer 214 is a layer designed to permit electrons to tunnel between the reference system 204 and the free layer 216 when a bias voltage is applied to electrodes of the TMR sensing element 200 (not shown) in order to provide the TMR effect. The tunnel barrier layer 214 may be, for example, an MgO layer having a thickness in a range from approximately 0.7 nm to approximately 1.5 nm.

The free layer 216 is a structure for which a direction of magnetization changes (e.g., rotates) in response to an external magnetic field applied at the TMR sensing element 200. As shown in FIG. 2A, the free layer 216 is a multilayer structure that may include the first CoFeB layer 218, the interlayer 220, the second CoFeB layer 222, and the NiFe layer 224.

In some implementations, CoFeB is used in the free layer 216 to increase the TMR effect at the tunnel barrier layer 214. In some implementations, the first CoFeB 218 has a thickness in a range from approximately 1.0 nm to approximately 4.0 nm, such as in a range from approximately 1.5 nm to approximately 2.5 nm. In some implementations, the second CoFeB layer 222 has a thickness in a range from approximately 0.5 nm to approximately 4.0 nm, such as in a range from approximately 1 nm to approximately 2.5 nm.

In some implementations, NiFe is used in the free layer 216 to facilitate rotation of the direction of magnetization of the free layer 216 by reducing coercivity of the free layer 216 (e.g., due to NiFe being a magnetically softer material as compared to, for example, CoFe). In some implementations, the NiFe layer 224 has a thickness in a range from approximately 5 nm to approximately 20 nm.

In some implementations, the interlayer 220 facilitates interlayer exchange coupling of the first CoFeB 218 and the second CoFeB layer 222. In one example, the interlayer 220 may be an MgO layer having a thickness in a range from approximately 0.1 nm to 0.5 nm, such as in a range from approximately 0.1 nm to approximately 0.3 nm. In another example, the interlayer 220 may be a tantalum (Ta) layer having a thickness in a range from approximately 0.1 nm to approximately 0.5 nm, such as in a range from approximately 0.2 nm to approximately 0.3 nm. In another example, the interlayer 220 includes an MgO layer and a tantalum (Ta) layer, each having a thickness in a range from approximately 0.1 nm to approximately 0.5 nm, such as in a range from approximately 0.1 nm to approximately 0.3 nm.

In some implementations, the first CoFeB layer 218 and the second CoFeB layer 222 in the free layer 216 serve to increase the TMR effect at the tunnel barrier layer 214. For example, a TMR effect in a TMR sensing element 200 with a free layer including a pair of CoFeB layers, each with a thickness of 1.5 nm, is 20% (or more) higher than a TMR effect in a compared to a conventional TMR sensing element 100 with a free layer including a single CoFeB layer with a thickness of 1.5 nm.

Further, the first CoFeB layer 218 and the second CoFeB layer 222 in the free layer 216 serve to decrease magnetostriction. For example, a conventional TMR sensing element 100 with a free layer including a single Co₂FeB layer with a thickness of 1.5 nm has a magnetostriction coefficient (λ) of 2.20. Conversely, a TMR sensing element 200 with a free layer including a pair of CoFeB layers, each with a thickness of 1.5 nm, has a magnetostriction coefficient of 0.96.

The cap layer 226 is a layer to provide electrical contact with a top electrode of the TMR sensing element 200 (not shown). The cap layer 226 may comprise, for example, tantalum (Ta), tantalum nitride (TaN), Ru, titanium (Ti), titanium nitride (TiN), or the like. In some implementations, the cap layer 226 may have a thickness in a range from approximately 10 nm to approximately 30 nm.

In some implementations, the TMR sensing element 200 may include a second interlayer. FIG. 2B is a diagram of an example implementation of the TMR sensing element 200 including a second interlayer 228. As shown, the second interlayer 228 may be arranged between the second CoFeB layer 222 and the NiFe layer 224. The second interlayer 228 may be, for example, a Ta layer having a thickness in a range from approximately 0.1 nm to approximately 0.5 nm, such as in a range from approximately 0.1 nm to approximately 0.3 nm. In some implementations, the second interlayer 228 may further increase the TMR effect at the tunnel barrier layer or may further reduce magnetostriction of the TMR sensing element 200.

As indicated above, FIGS. 2A and 2B are provided as examples. Other examples may differ from what is described with regard to FIGS. 2A and 2B. The number, arrangement, thicknesses, and relative thicknesses, of layers shown in FIGS. 2A and 2B are provided as an example. In practice, there may be additional layers, fewer layers, different layers, layers having different thicknesses, layers having different relative thicknesses, or differently arranged layers than those shown in FIGS. 2A and 2B. Furthermore, two or more layers shown in FIGS. 2A and 2B may be implemented within a single layer, or a single layer shown in FIGS. 2A and 2B may be implemented as multiple, distributed layers. Additionally, or alternatively, a set of layers (e.g., one or more layers) shown in FIGS. 2A and 2B may perform one or more functions described as being performed by another set of layers shown in FIGS. 2A and 2B.

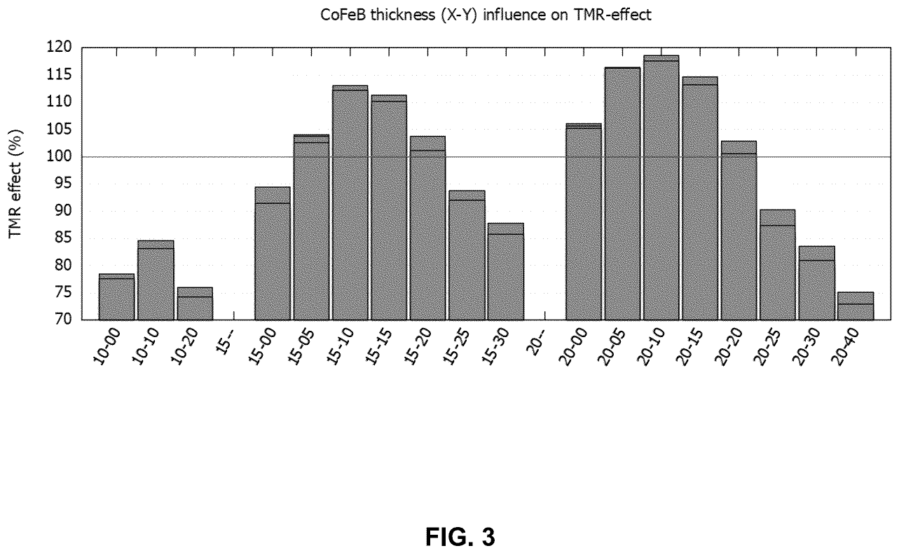

FIG. 3 is a diagram illustrating examples of TMR effect increases provided by the TMR sensing element 200 including the first CoFeB layer 218 and the second CoFeB layer 222.

Points along the horizontal axis in FIG. 3, indicate thicknesses (in angstroms (Å)) of CoFeB layers in a free layer of a TMR sensing element. For example, the first point on the horizontal axis (10-00) indicates a free layer including a first CoFeB layer having a thickness of 1.0 nm (10 Å) and a second CoFeB layer having a thickness of 0.0 nm (0 Å) (i.e., no second CoFeB layer) (e.g., as in the case of the conventional TMR sensing element 100). Similarly, the second point on the horizontal axis (10-10) indicates a free layer including to a first CoFeB layer having a thickness of 1.0 nm (10 Å) and a second CoFeB layer having a thickness of 1.0 nm (10 Å) (e.g., as in the case of one example of a TMR sensing element 200).

As can be seen in FIG. 3, a free layer that includes a second CoFeB layer (i.e., a second CoFeB layer with a non-zero thickness) provides a higher TMR effect than a free layer that includes a single CoFeB layer when the thickness of the second CoFeB layer is less than or equal to the thickness of the first CoFeB layer. Notably, however, as the thickness of the second CoFeB layer surpasses the thickness of the first CoFeB layer, the TMR effect decreases.

As indicated above, FIG. 3 is provided as an example. Other examples may differ from what is described with regard to FIG. 3.

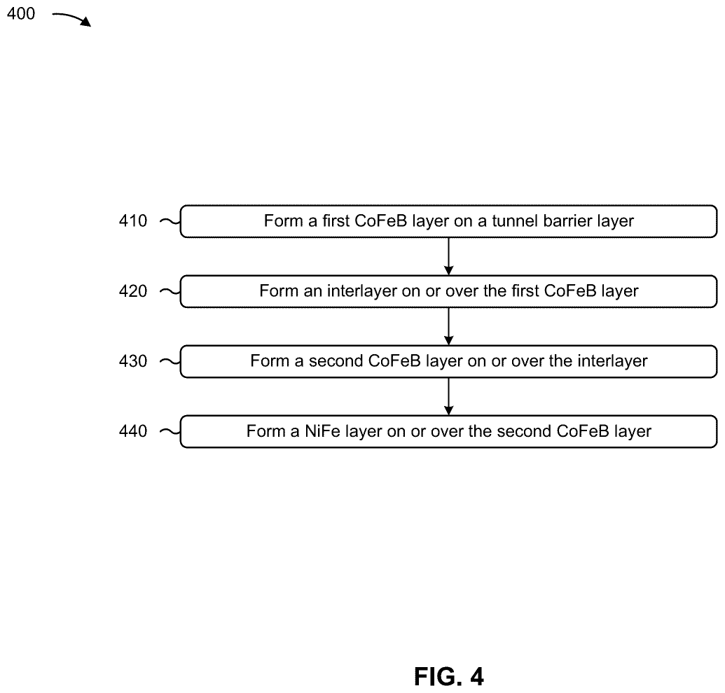

FIG. 4 is a flowchart of an example process 400 associated with fabricating the TMR sensing element 200 including the first CoFeB layer and the second CoFeB layer 222.

As shown in FIG. 4, process 400 may include forming a first CoFeB layer on a tunnel barrier layer (block 410). For example, a first CoFeB layer 218 may be formed on a tunnel barrier layer 214, as described above.

As further shown in FIG. 4, process 400 may include forming an interlayer on or over the first CoFeB layer (block 420). For example, an interlayer 220 may be formed on or over the first CoFeB layer 218, as described above.

As further shown in FIG. 4, process 400 may include forming a second CoFeB layer on or over the interlayer (block 430). For example, a second CoFeB layer 222 may be formed on or over the interlayer 220, as described above.

As further shown in FIG. 4, process 400 may include forming a NiFe layer on or over the second CoFeB layer (block 440). For example, a NiFe layer 224 may be formed on or over the second CoFeB layer 222, as described above.

Process 400 may include additional implementations, such as any single implementation or any combination of implementations described below and/or in connection with one or more other processes described elsewhere herein.

In a first implementation, the second CoFeB layer 222 has a thickness in a range from approximately 1 nm to approximately 2 nm.

In a second implementation, alone or in combination with the first implementation, the first CoFeB layer 218 has a thickness in a range from approximately 1 nm to approximately 2 nm.

In a third implementation, alone or in combination with one or more of the first and second implementations, the NiFe layer 224 has a thickness in a range from approximately 5 nm to approximately 15 nm.

In a fourth implementation, alone or in combination with one or more of the first through third implementations, the interlayer 220 is a first interlayer, and the method further comprises forming a second interlayer 228, the second interlayer 228 being between the second CoFeB layer 222 and the NiFe layer 224.

In a fifth implementation, in combination with the fourth implementation, the second interlayer has a thickness in a range from approximately 0.1 nm to approximately 0.3 nm.

In a sixth implementation, in combination with one or more of the fourth and fifth implementations, the second interlayer 228 comprises tantalum.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items,), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

1. A tunnel magnetoresistive (TMR) sensing element, comprising:
a free layer including:
a first cobalt iron boron (CoFeB) layer;
an interlayer over the first CoFeB layer;
a second CoFeB layer over the interlayer; and
a nickel iron (NiFe) layer directly on the second CoFeB layer; and
a reference system including:
a reference layer below the CoFeB layer; and
a pinned layer below the reference layer,
wherein the reference layer and the pinned layer are configured with opposite directions of magnetization.

2. The TMR sensing element of claim 1, wherein the second CoFeB layer has a thickness in a range from 0.5 nanometer to 4 nanometers.

3. The TMR sensing element of claim 1, wherein the interlayer is at least one of magnesium oxide (MgO) or tantalum (Ta).

4. The TMR sensing element of claim 1, wherein the interlayer has a thickness in a range from 0.1 nanometers to 0.5 nanometers.

5. The TMR sensing element of claim 1, wherein the first CoFeB layer has a thickness in a range from 1 nanometer to 4 nanometers.

6. The TMR sensing element of claim 1, wherein the NiFe layer has a thickness in a range from 5 nanometers to 20 nanometers.

7. The TMR sensing element of claim 1, wherein the interlayer is a first interlayer, and the TMR sensing element further comprises a second interlayer between the second CoFeB layer and the NiFe layer.

8. The TMR sensing element of claim 7, wherein the second interlayer has a thickness in a range from 0.1 nanometers to 0.5 nanometers.

9. The TMR sensing element of claim 7, wherein the second interlayer comprises tantalum.

10. A sensor, comprising:
a magnetoresistive (MR) sensing element including:
a seed layer;
a reference layer over the seed layer;
a pinned layer below the reference layer,
wherein the reference layer and the pinned layer are configured with opposite directions of magnetization;
a tunnel barrier layer over the reference layer;
a free layer over the tunnel barrier layer,
wherein the free layer includes:
a first cobalt iron boron (CoFeB) layer,
a second CoFeB layer,
an interlayer between the first CoFeB layer and the second CoFeB layer, and
a nickel iron (NiFe) layer on the second CoFeB layer; and
a cap layer on the free layer.

11. The sensor of claim 10, wherein the second CoFeB layer has a thickness in a range from 1 nanometer to 4 nanometers.

12. The sensor of claim 10, wherein the first CoFeB layer has a thickness in a range from 1 nanometer to 4 nanometers.

13. The sensor of claim 10, wherein the NiFe layer has a thickness in a range from 5 nanometers to 20 nanometers.

14. The sensor of claim 10, wherein the interlayer is a first interlayer, and the free layer further includes a second interlayer, the second interlayer being between the second CoFeB layer and the NiFe layer.

15. The sensor of claim 14, wherein the second interlayer has a thickness in a range from 0.1 nanometers to 0.5 nanometers.

16. A method, comprising:
forming a first cobalt iron boron (CoFeB) layer on a tunnel barrier layer;
forming an interlayer on or over the first CoFeB layer;
forming a second CoFeB layer on or over the interlayer;
forming a nickel iron (NiFe) layer on the second CoFeB layer;
forming a reference layer below the first CoFeB layer, and
forming a pinned layer below the reference layer,
wherein the reference layer and the pinned layer are configured with opposite directions of magnetization.

17. The method of claim 16, wherein the second CoFeB layer has a thickness in a range from 1 nanometer to 4 nanometers.

18. The method of claim 16, wherein the first CoFeB layer has a thickness in a range from 1 nanometer to 4 nanometers.

19. The method of claim 16, wherein the NiFe layer has a thickness in a range from 5 nanometers to 20 nanometers.

20. The method of claim 16, wherein the interlayer is a first interlayer, and the method further comprises forming a second interlayer, the second interlayer being between the second CoFeB layer and the NiFe layer.
